(19) United States
(12) Patent Application Publication
(10) Pub. No.: US 2023/0358817 A1
(43) Pub. Date: Nov. 9, 2023

(54) METHOD AND DEVICE FOR DETERMINING THE IMPEDANCE OF A RECHARGEABLE ELECTRICAL ENERGY STORAGE

(71) Applicant: Phoenix Contact GmbH & Co. KG, Blomberg (DE)

(72) Inventors: Eugen Mantler, Steinheim (DE); Srishtik Prasad Kayastha, Paderborn (DE)

(21) Appl. No.: 18/307,822

(22) Filed: Apr. 27, 2023

(30) Foreign Application Priority Data
Apr. 29, 2022 (LU) LU501973

(51) Int. Cl. G01R 31/3835; G01R 31/389

(52) U.S. Cl. CPC G01R 31/3835; G01R 31/389

(57) ABSTRACT

A method of determining an internal resistance of a rechargeable electrical energy storage includes: detecting a first voltage of the energy storage while a first current magnitude is drained from the energy storage; detecting a second voltage of the energy storage while a second current magnitude is drained from the energy storage, the second current magnitude being larger than the first current magnitude; implementing a periodic switch-over between the drain of the first current magnitude and the drain of the second current magnitude; and determining the internal resistance based on the detected first and second voltages, which are detected by the periodic switch-over between the first and second current magnitudes.

### CROSS-REFERENCE TO PRIOR APPLICATION

Priority is claimed to Luxembourg Patent Application No. LU 501973 filed on Apr. 29, 2022, the entire disclosure of which is hereby incorporated by reference herein.

### FIELD

The invention relates to a method and a device for determining the impedance of a rechargeable electrical energy storage. Without being limited thereto, it relates in particular to a cost-efficient determination of the impedance of batteries with different capacities and different chemical processes without prior adaptation of a corresponding determination circuit.

### BACKGROUND

Batteries, which ensure the operation of the power supply even in the case of a temporary failure of an external supply voltage (for example a supply voltage provided by the general power suppliers, also referred to as primary supply voltage), are often used in different interruption-free power supplies. In particular in the case of short-term interruptions of the primary supply voltage, the interruption-free supply of the loads, which are connected to the uninterruptible power supply, can be ensured in this way, in order to avoid disturbances or interferences at the loads in this way. For this purpose, it is necessary to regularly determine the proper state of the battery, which can also be referred to as buffer battery, and to inform the user about a corresponding malfunction, if necessary. Currently known measuring methods of the battery impedance use measurements with alternating current, in technical terms also referred to as AC measurement (for “Alternating Current”). They generally provide good results. Alternatively, measurements with direct current values are also known, in technical terms also referred to as DC measurement (for “Direct Current”). They can be realized more easily for which reason these measurements are implemented more cost-efficiently.

However, the measurements with alternating current require a relatively complex and costly measuring apparatus. The latter is uneconomical in particular when using high quantities in a cost-conscious environment. The measurement with direct current values becomes inaccurate in the case of higher battery capacities. They are therefore not well suited for the use of a broad spectrum of battery capacities. The measurement of the battery state is thus either cost-intensive or a plurality of different measuring apparatuses is necessary, depending on the battery capacity.

To measure a battery capacity, the publication BU-902: “How to Measure Internal Resistance”, Battery University, proposes a measuring method with two different direct current magnitudes (or DC amperages), which are drained successively from the battery. The ohmic resistance of the battery can be determined therefrom.

### SUMMARY

In an embodiment, the present invention provides a method of determining an internal resistance of a rechargeable electrical energy storage, comprising: detecting a first voltage of the energy storage while a first current magnitude is drained from the energy storage; detecting a second voltage of the energy storage while a second current magnitude is drained from the energy storage, the second current magnitude being larger than the first current magnitude; implementing a periodic switch-over between the drain of the first current magnitude and the drain of the second current magnitude; and determining the internal resistance based on the detected first and second voltages, which are detected by the periodic switch-over between the first and second current magnitudes.

### BRIEF DESCRIPTION OF THE DRAWINGS

Subject matter of the present disclosure will be described in even greater detail below based on the exemplary figures. All features described and/or illustrated herein can be used alone or combined in different combinations. The features and advantages of various embodiments will become apparent by reading the following detailed description with reference to the attached drawings, which illustrate the following:

FIG. 1 shows a flowchart for a method for determining an internal resistance of a rechargeable electrical energy storage according to an embodiment of the first aspect,

FIG. 2 shows a schematic current-voltage curve diagram of an idealized battery during a measuring process for determining the internal resistance of the battery with two current magnitudes according to an embodiment of each aspect,

FIG. 3 shows a schematic current-voltage curve diagram of an actual battery during a measuring process for determining the internal resistance of the battery with two current magnitudes according to an embodiment of each aspect,

FIG. 4 shows a schematic illustration of a controllable measuring circuit with connected battery for determining an internal resistance of the battery according to an embodiment of each aspect,

FIG. 5 shows a schematic illustration of an electrical circuit of a controller with connected battery for determining an internal resistance of the battery according to an embodiment of the second aspect, and

FIG. 6 shows a schematic illustration of an uninterruptible (or interruption-free) power supply according to an embodiment of the third aspect.

### DETAILED DESCRIPTION

In an embodiment, the present invention provides a technique, by means of which the internal resistance of batteries with different capacities can be determined cost-efficiently and without adapting the measuring apparatus to the battery capacity.

Exemplary embodiments of the invention, which can optionally be combined with one another, are disclosed below with partial reference to the figures.

A first aspect relates to a method of determining an internal resistance of a rechargeable electrical energy storage. The method comprises a detection of a first voltage of the energy storage while a first current magnitude (or first amperage) is drained from the energy storage. The method further comprises a detection of a second voltage of the energy storage while a second current magnitude (or second amperage), which is larger than the first current magnitude, is drained from the energy storage. The method additionally comprises that a periodic switch-over takes place between the drain of the first current magnitude and the drain of the second current magnitude. Optionally, the method further comprises a determination of the internal resistance based on the detected first and second voltages, which are detected in the case of the periodically switched-over first and second current magnitudes.

The ohmic internal resistance of the rechargeable electrical energy storage in the case of different capacities can advantageously be determined in this way with good accuracy by means of a measuring method, which is simple and which can thus be realized cost-efficiently.

For batteries with a low and average capacity, in particular in the case of capacities between 1 Ah and 100 Ah, the internal resistance can thereby be measured with sufficient accuracy. Advantageously, only the voltages have to be measured alternately during two different current magnitudes for this purpose.

In addition to the first current magnitude and the second current magnitude, the method can optionally be configured to also drain a third current magnitude (or third amperage) and optionally also a fourth current magnitude (or fourth amperage) and optionally also a fifth current magnitude (or fifth amperage) from the battery. All of the respectively selected current magnitudes are switched over periodically. Advantageously, the internal resistance of batteries with larger capacity can also be determined sufficiently accurately in this way. For example, the battery capacity can thereby be up to 100 Ah or even beyond that up to over 200 Ah.

The internal resistance can be determined based on a subset of the detected first and second voltages. The observation that at the beginning of a periodic current drain the voltage at the battery poles drops strongly, and also changes significantly in the first periods, can thereby be used in an advantageous manner. In the case of each further period, the voltage increases thereby while the voltage difference to the previous period becomes smaller at the same time. After a number of measuring periods with the different current magnitudes, the voltage reaches a relatively constant value. By suppressing the strong voltage drops, the relatively constant voltage can therefore be considered in an advantageous manner to determine the internal resistance, in order to reach constant voltage values during the respective current drain.

For example, the last 10 measuring periods from 40 measuring periods can correspond to the subset at the end of a measuring process, wherein each measuring period can comprise the drain of the first current magnitude and subsequently the drain of the second current magnitude. Alternatively, the first 30 measuring periods can correspond to the subset at the beginning of a measuring process. It can also be provided to use a combination of both subsets. A medium range of the respective measured voltages can thus be selected in an advantageous manner.

The first voltage and the second voltage also vary during the respective current drain. Optionally, by averaging the individual measured voltage curves during the respective current drain, the measuring accuracy can be further improved. For example, the averaging can take place according to an RMS method (in technical terms referred to as “root mean square” or effective value).

The subset of the detected first and second voltages can comprise a subset of the first and second voltages, which is detected towards the temporal end of a constant (first or second) current magnitude. Additionally or alternatively, a subset of the first and second voltages detected at the beginning of a measuring process can further be excluded. This applies accordingly for possible third and further voltages, which are based on corresponding third and further current drains.

The detected subset of the first and second voltages can optionally be a specified number of voltages. For example, the last 25% of the detected voltages can correspond to the subset at the end of a measuring process. The last 20% or 30% of the detected voltages can also correspond to the subset at the end of a measuring process. The ratio of the detected and excluded first and second voltages can further optionally be set. This can take place automatically on the basis of identified properties of the rechargeable electrical energy storage, for example the nominal voltage or the no-load voltage (or open circuit voltage) of the electrical energy storage. Alternatively or additionally, it can also be determined by means of user inputs.

The consideration of the first and second voltages detected during the measuring process can advantageously be selected flexibly in this way in order to consider, for example, special features of certain rechargeable electrical energy storages, which can be configured, for example, as batteries.

During the excluded beginning of the measuring process, a change rate of the first voltage and/or of the second voltage can be larger than a first threshold value. Additionally or alternatively, a change rate of the first voltage and/or of the second voltage can be smaller than a second threshold value during the subset detected towards the end of the measuring process. The change rate can thereby refer to consecutive values of the first voltage and/or of the second voltage. Alternatively, non-consecutive values of the first voltage and/or of the second voltage can also be considered for the threshold value. The second threshold value can optionally be smaller than or equal to the first threshold value.

First voltages and/or second voltages with similar values can advantageously be considered for an evaluation in this way. The evaluation quality can thus be improved. It is further advantageous to be able to consider different change rates. The properties of the respectively present rechargeable electrical energy storage can be reacted to flexibly in this way.

A further improvement can be attained by means of the selectability of the first threshold value and of the second threshold value in order to consider special features of certain rechargeable electrical energy storages, which can be configured, for example, as batteries. The determination of the first threshold value and/or of the second threshold value can take place automatically, for example on the basis of identified properties of the rechargeable electrical energy storage, for example of the nominal voltage or of the no-load voltage of the electrical energy storage. Alternatively or additionally, it can also be determined by means of user inputs.

To determine the internal resistance per duration of the first and second current magnitude, the first or second voltage, respectively, can be detected only in one section of the duration. The detection can optionally take place at the end or in a last section of the duration of the first or second current magnitude, respectively. For example, the last section of the duration can comprise one-fourth per duration, i.e. 25%, of the first and second current magnitude or of the first or second voltage, respectively. However, it can also comprise 20% or 30% per duration. The detection can further optionally take place at the beginning or in a first section of the duration of the first or second current magnitude, respectively. The determination of the duration and the positioning thereof in the last or first section of the duration can thereby take place automatically, for example on the basis of identified properties of the rechargeable electrical energy storage. It can optionally be derived from the voltage curve of the first or second voltage during the duration. It can alternatively or additionally also be determined by means of user input. A switch-over can further optionally take place between the detection of the first section and the detection of the last section of the voltage. The switch-over can be based on a threshold value. In embodiments, the threshold value can be based on the change rate of the first voltage and/or of the second voltage.

It is observable that the first or second voltage can change during the duration of the first and second current magnitude, respectively. The values determined for the further processing can therefore be limited in an advantageous manner by means of the only partial consideration of the voltages (for example of the voltage curves), for example to the respective highest values of the first or second voltage, respectively. They can also lie in the beginning or in a first section of the duration. Alternatively or additionally, the largest and the smallest value can be excluded from a sequence of sampling values per duration, in order to rule out measuring errors, or a median can be determined as voltage from the sequence of sampling values per duration.

The first and second current magnitude can each be constant. They can have a curve of the current magnitude, which is formed as rectangle. The curve can advantageously be realized by means of switches, which can be configured, for example, as relays or transistors and which thus allow for a simple and cost-efficient realization.

The duration of the drain of the first and second current magnitude can be identical. Additionally or alternatively, a duty cycle of the first and second current magnitude (i.e. a temporal proportion of the respective duration in the period duration of the switch-over) can be independent of the capacity of the rechargeable electrical energy storage. Further additionally or alternatively, a frequency of the periodic switch-over can be independent of the capacity of the rechargeable electrical energy storage. Alternatively, the duty cycle can also be adapted to the capacity of the rechargeable electrical energy storage. An identical setting can advantageously be maintained in this way for many battery types and capacities, which reduces the installation and maintenance effort. The measuring accuracy can further advantageously be improved for special batteries and/or capacities by adapting the duty cycle.

The rechargeable electrical energy storage can comprise electrochemical cells. A nominal voltage or no-load voltage of the rechargeable electrical energy storage can thereby lie in the range from 12 V to 48 V. Additionally or alternatively, a capacity of the rechargeable electrical energy storage can lie in the range from 1 Ah to 100 Ah. Alternatively, capacities above 200 Ah can also be used. In the case of capacities above 200 Ah, a third current magnitude and optionally also a fourth current magnitude and optionally also a fifth current magnitude can furthermore be drained from the battery in addition to the first current magnitude and the second current magnitude, as already noted above. All of the respectively selected current magnitudes can be switched over periodically (for example cyclically). The measuring accuracy can advantageously be increased in this way in the case of large capacities.

In order to drain the first current magnitude, the rechargeable electrical energy storage can be discharged via a first resistor, and via a second resistor in order to drain the second current magnitude. The drain of the second current magnitude can alternatively take place via a parallel connection of the first resistor and of a second resistor. Measuring values (or data) of resistors of a measuring apparatus, on which the first current magnitude and the second current magnitude are based, can thereby be stored in the measuring apparatus. The measuring values can be determined during a calibration of the measuring apparatus. The measuring values of the resistors of the measuring apparatus can thereby optionally be at least ten times larger than the internal resistance of the rechargeable electrical energy storage. The resistors for the first current magnitude can further optionally be 7.5 ohm (7.5 Ω) and can be 3.75 ohm for the second current magnitude. Discharge currents of 4.5 A or 9.0 A, respectively, can advantageously be achieved in this way, which contribute to the improvement of the measuring accuracy. In the case of these or similar current magnitudes, a significant voltage drop of the terminal voltage of the energy storage (as first and second voltage) can be detected compared to the no-load voltage on the one hand, and the Joule heat can be removed without thermal damages with a sufficient rate of the heat transport at the measuring resistors on the other hand.

In each exemplary embodiment, the measurement of the first current magnitude and of the second current magnitude can advantageously be forgone by storing the measuring values of resistors in the measuring apparatus, which simplifies the measuring apparatus.

When periodically switching over between the first and second current magnitude, a switch-over can take place between the first and the second resistor by means of a field effect transistor. Alternatively, the second resistor can be connected in parallel to the first resistor by means of a field effect transistor. A frequency of the periodic switch-over can thereby optionally be larger than or equal to 100 Hz. The frequency of the periodic switch-over can lie between 100 Hz and 5 kHz in this way. The accuracy of the measurement is further increased in an advantageous manner in this way. Further advantageously, a limitation of the level of the switch-over frequency is avoided with the use of the field effect transistors. Installation space is additionally saved when realizing the solution.

The measuring values can be corrected by the resistance of electrically conductive connecting elements between the electrical energy storage and the measuring apparatus. The resistance can optionally be limited to the ohmic proportion (real portion of the resistance). The resistance of the electrically conductive connecting elements can further optionally be stored in the measuring apparatus. This can be a measured value, which is measured during the manufacture of the measuring apparatus. Alternatively, it can also be a constant value, which is stored during the manufacture. Further alternatively, the value can also be ignored if it lies below a predefined threshold. In embodiments, the threshold can be 1 milliohm (mΩ). Alternatively or additionally, the resistance can be input by an operator. The measuring accuracy can advantageously be improved further in this way by reducing the determined resistance of battery and electrically conductive connecting elements by the resistance of the electrically conductive connecting elements.

Alternatively, the first current magnitude and the second current magnitude can be kept constant by means of a regulation (or feedback control). Possible resistance changes of ohmic components with regard to age, heat-up, or other environmental influences, which would reduce the measuring quality, can advantageously be countered in this way.

The first current magnitude and the second current magnitude can have a ratio of 1 to 2. As an example, the first current magnitude can be 4.5 A and the second current magnitude can be 9.0 A. The selected current magnitudes advantageously allow for the measurement of the internal resistance at capacities of the electrical energy storages between 1 Ah and 100 Ah, in particular between 1 Ah and 50 Ah, because the battery load and the resulting voltage difference are in balance. If more than 2 current magnitudes are optionally used during the periodic measurement, for example during the measurement of an energy storage with more than 100 Ah, in particular of more than 200 Ah, each further current magnitude can in each case be increased by the amount of the first current magnitude, based on the previous current magnitude.

A second aspect relates to a controller for determining an internal resistance of a rechargeable electrical energy storage. The controller can thereby further be configured to perform the steps of the exemplary embodiment of the first aspect as well as some or several of the above-mentioned optional steps. A cost-efficient measuring apparatus for determining an internal resistance of rechargeable electrical energy storages, for example in the form of batteries, can advantageously be provided in this way. The controller can correspond to the measuring apparatus. The controller can be integrated into the battery. The internal resistance can be displayed by means of a (for example linear) display on the housing of the battery. The controller can further advantageously be designed to be functionally integrated into a device (for example into a vehicle or an interruption-free power supply).

The controller can optionally further be configured to determine the internal resistance (i.e. the impedance) at regular time internals and to analyze the change tendency. In the case of specified deviations of the internal resistance, the user can be informed about the state of the battery in this way. Advantageously, it is possible to identify or to differentiate a creeping or a sudden change of the internal resistance of the battery by means of this measuring and evaluation method. An aging process of the battery can further be derived from this value, and a defect of the battery can further be identified in due time.

A third aspect relates to an uninterruptible (or interruption-free) power supply (UPS). The latter can comprise a rechargeable electrical energy storage or can be capable of being electrically conductively connected thereto. It can comprise the controller for determining an internal resistance of the rechargeable electrical energy storage according to the second aspect. A cost-efficient monitoring function, which, on the basis of the determined internal resistance of the connected battery, can check the functionality of the latter, can advantageously be integrated into the interruption-free power supply in this way.

A rechargeable electrical energy storage can be configured as battery, which stores electrical energy on electrochemical basis. Lithium-, lead-, nickel-, sodium-, silver-, tin-based accumulators are possible as battery types, without being limited to these embodiment types.

A measuring process can comprise a plurality of the periodically switched-over first and second current magnitudes. If necessary, it may also comprise further current magnitudes, as is described above. The measuring process may typically comprise between 30 and 60 measuring periods, in particular 40 measuring periods, whereby each measuring period can comprise the drain of the first current magnitude and subsequently the drain of the second current magnitude. The measuring periods can immediately follow one another during the measuring process.

A duty cycle may specify (or indicate) the ratio of the pulse duration (i.e. of the respective durations) to the period duration for a periodic sequence of pulses (for example current magnitudes).

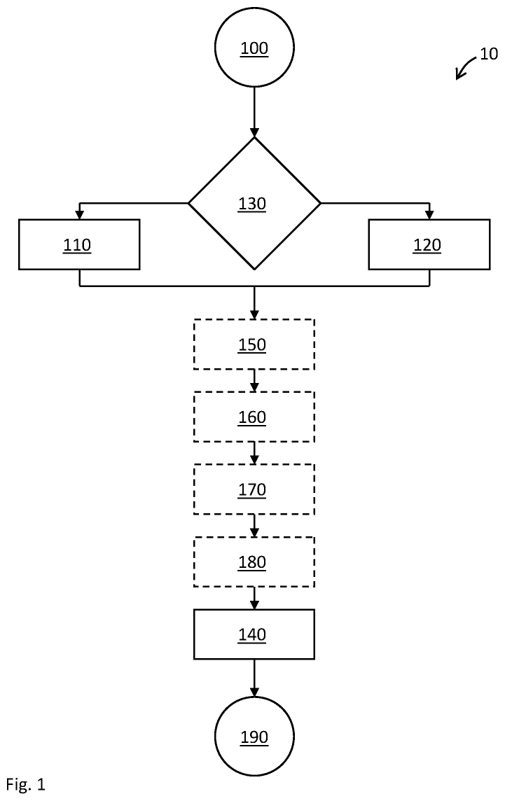

In a first aspect, FIG. 1 relates to a method 10 for determining an internal resistance of a rechargeable electrical energy storage. The energy storage is generally identified below with reference numeral 400. The electrical energy storage 400 is configured as battery, which can be based on various chemical principles.

In a first step, the method 10 comprises a detection 110 of a first voltage of the energy storage 400, while a first current magnitude is drained from the energy storage 400. In a second step, the method 10 further comprises a detection 120 of a second voltage of the energy storage 400, while a second current magnitude is drained from the energy storage 400. The second current magnitude is thereby larger than the first current magnitude. Additionally, the method 10 comprises a periodic switch-over 130 between the drain 110 of the first current magnitude and the drain 120 of the second current magnitude. In other words, the first current magnitude is drained first in a first period. The second current magnitude is drained subsequently. In turn, the first current magnitude is drained afterwards in a second period, and the second current magnitude is drained afterwards and so forth.

The method 10 can further determine the internal resistance in a step 140, based on the first and second voltages, which are detected in steps 110 and 120 and which are detected in the case of the periodically switched-over first and second current magnitudes.

The internal resistance can be determined, for example, by means of a uniform measuring method for batteries 400 with a capacity of between 1 Ah up to 100 Ah, i.e. the internal resistance can be measured with sufficient accuracy. In the case of battery capacities of up to 50 Ah, an improved measuring accuracy is attained thereby.

The method 10 can further optionally determine the internal resistance based on a subset 209 of the detected first and second voltages, for example by means of a corresponding processing step 150 of the method 10. A measuring process is identified herein with reference numeral 208 and the subset optionally with reference numeral 209.

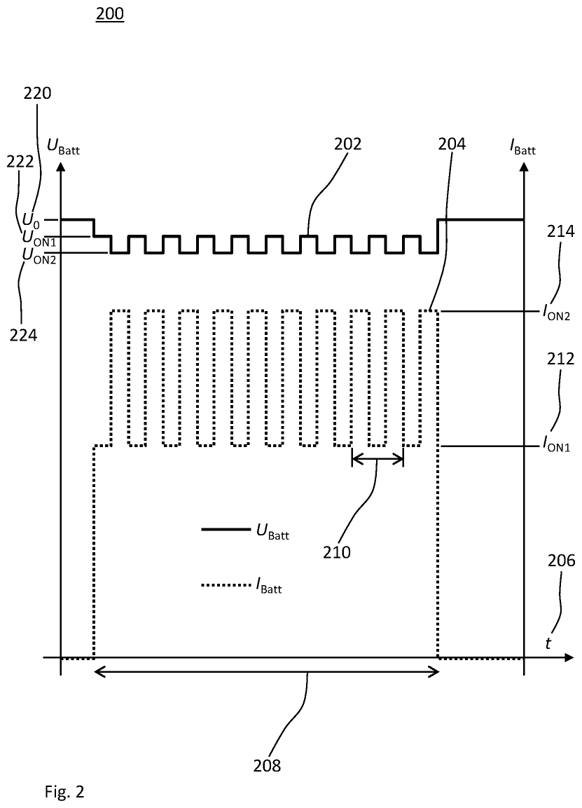

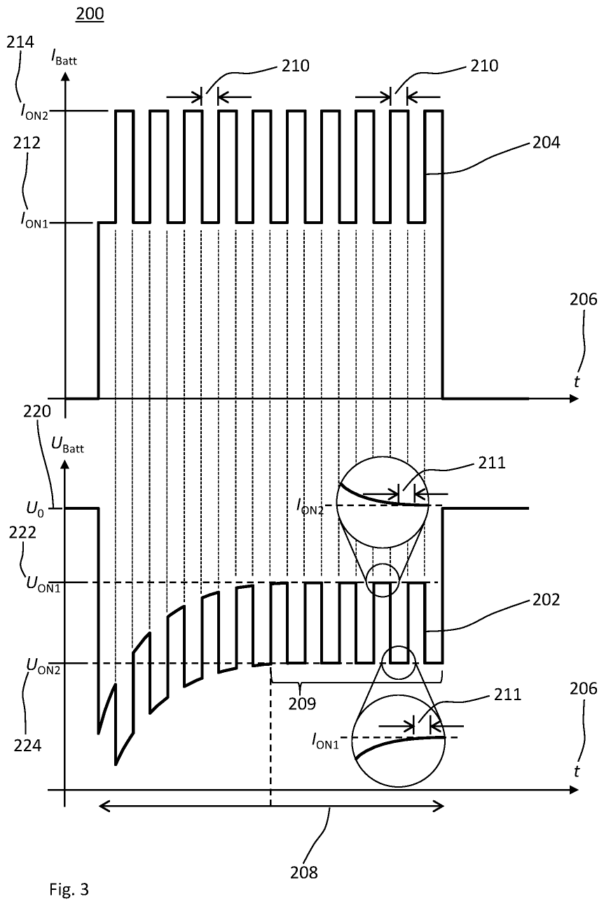

The observation that the voltage, which is generally identified with reference numeral 202, drops strongly at the battery terminals and/or also changes significantly in the first periods at the beginning of a periodic current drain, is utilized thereby. The latter can mean that the battery voltage changes during a constant current drain, i.e. during the respective duration, which will be identified below with reference numeral 210. The voltage as a whole thereby increases in the case of each further period while the voltage difference to the previous period becomes smaller at the same time. After a number of measuring periods with the different current magnitudes, the voltage reaches a relatively constant value. By suppressing the strong voltage drops at the beginning of a measuring process, the relatively constant voltage is therefore considered in order to determine the internal resistance. A limitation to the constant voltage values during the respective current drain is attained in this way. This feature is described in more detail with FIGS. 2 and 3, see below.

For example, the last 10 measuring periods from 40 measuring periods can correspond to the subset at the end of the measuring process, whereby each measuring period comprises the drain of the first current magnitude and subsequently the drain of the second current magnitude. Alternatively, the first 30 measuring periods can correspond to the subset at the beginning of a measuring process. It can also be provided to use a combination of both subsets. A medium range of the respective measured voltages can thus be selected in an advantageous manner.

Due to the fact that the first voltage and the second voltage can vary during the respective current drain, the measuring accuracy can optionally be improved further by averaging or forming the median of the individual measured voltage curves during the respective current drain. For example, the averaging can take place according to the RMS method (“root mean square”).

The subset of the detected first and second voltages can optionally comprise a subset of the first and second voltages, which is detected towards the temporal end of a constant (first or second) current magnitude, for example by means of a processing step 160. The voltage measurement can take place during the duration of the respective current magnitude, which is identified with reference numeral 210 herein. The section of the detection is optionally identified with reference numeral 211. In other words, the voltage curve is not considered completely during constant current drain. Instead, only a section 211 of the current curve is considered, here the rear section 211 at the temporal end of the drained constant current, i.e. at the end of the duration 210. A subset of the first and second voltages detected at the beginning of a measuring process is therefore excluded. This applies accordingly for third and further voltages, which are based on third and further current drains.

The detected subset 209 of the first and second voltages can optionally be a specified number of voltages. For example, the last 25% of the detected voltages can correspond to the subset 209 at the end of a measuring process 208. The last 20% or 30% of the detected voltages can also correspond to the subset at the end of a measuring process 208.

The ratio of the detected and excluded first and second voltages can further optionally be set. This can take place automatically on the basis of identified properties of the battery 400. Alternatively or additionally, it can also be determined by means of user inputs.

During the excluded beginning of the measuring process, a change rate of the first voltage and/or of the second voltage can optionally be larger than a first threshold value, for example according to a corresponding processing step 170 of the method 10. Additionally or alternatively, a change rate of the first voltage and/or of the second voltage can be smaller than a second threshold value during the subset 209 detected towards the end of the measuring process 210, for example according to a corresponding processing step 170 of the method 10. The change rate can thereby refer to consecutive values of the first voltage and/or of the second voltage. Alternatively, non-consecutive values of the first voltage and/or of the second voltage can also be considered for the threshold value. This can be every 2^{nd} or every 3^{rd} voltage. The second threshold value can further be smaller than or equal to the first threshold value.

First voltages and/or second voltages with similar values can advantageously be considered for an evaluation in this way. The evaluation quality can thus be improved. It is further advantageous to be able to consider different change rates. The properties of the respectively present battery can be reacted to flexibly in this way.

A further improvement can be attained by means of the selectability of the first threshold value and of the second threshold value in order to consider special features of certain rechargeable batteries 400. The determination of the first threshold value and/or of the second threshold value can take place automatically, for example on the basis of identified properties of the battery, of the chemical principle, or of the capacity. Alternatively or additionally, it can also be determined by means of user input.

To determine the internal resistance, the first or second voltage, respectively, can be detected per duration of the first and second current magnitude only in one section 211 of the duration 210, for example by means of a corresponding processing step 180 of the method. The detection can optionally take place at the end or in a last section 211 of the duration 210 of the first or second current magnitude, respectively. For example, the last section 211 of the duration 210 can comprise one-fourth of the duration, i.e. 25%, of the first and second current magnitude or of the first or second voltage, respectively. However, it can also comprise 20% or 30% of the duration. Alternatively or additionally, the detection can also take place at the beginning or in a first section of the duration 210 of the first or second current magnitude, respectively. The determination of the duration 210 and the positioning of the section 211 therein (for example as last or first section) can thereby take place automatically, for example on the basis of identified properties of the battery 400, of the chemical principle of the battery 400, or of the capacity of the battery 400. It can optionally also be derived from the voltage curve of the first or second voltage during the duration. It can alternatively or additionally also be determined by means of user input. A switch-over can further optionally take place between the detection of the first section and the detection of the last section 211 of the voltage. The switch-over can be based on a threshold value. In embodiments, the threshold value can be based on the change rate of the first voltage and/or of the second voltage.

It is important to note that the first or second voltage, respectively, can change during the duration 210 of the first and second current magnitude. The values determined for the further processing can therefore be limited in an advantageous manner by means of the only partial consideration of the voltages (of the voltage curves) in a section 211, for example to the respective highest values of the first or second voltage, respectively. They can also lie at the beginning or in a first section of the duration. This property is described in more detail by means of FIGS. 2 and 3, see below.

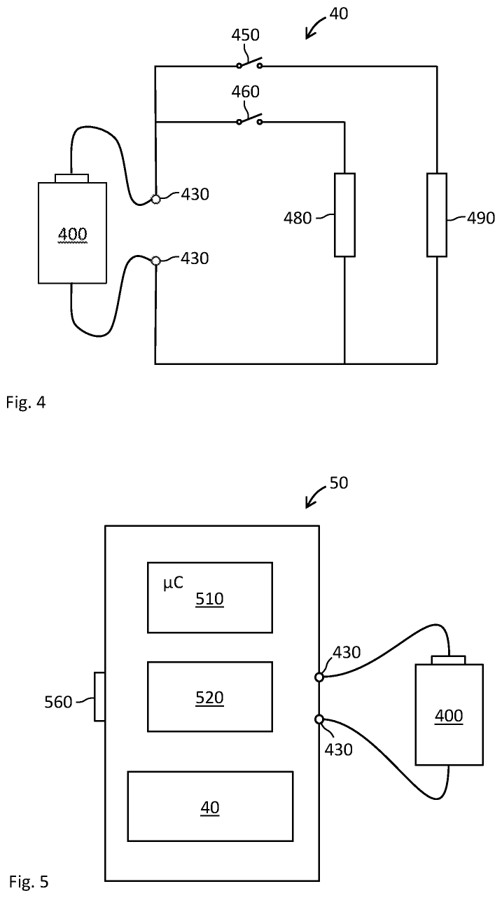

The first and second current magnitude can each be constant. They can thereby have a curve of the current magnitude, which is formed as rectangle (see, for example, FIGS. 3 and 4). The curve can advantageously be realized by means of switches, which can be configured, for example, as relays or transistors (for example field effect transistors) and which thus allow for a simple and cost-efficient realization.

The duration of the drain of the first and second current magnitude can be identical (see, for example, FIGS. 3 and 4). Additionally or alternatively, a duty cycle of the first and second current magnitude can be independent of the period duration of the switch-over. Further additionally or alternatively, a frequency of the periodic switch-over can be independent of the capacity of the battery. Alternatively, the duty cycle can also be adapted to the capacity of the battery. An identical setting can advantageously be maintained in this way for many battery types and capacities, which reduces the installation and maintenance effort. The measuring accuracy can further advantageously be improved for special batteries and/or capacities by adapting the duty cycle.

The battery comprises electrochemical cells. A nominal voltage of the battery can thereby lie in the range from 24 V to 48 V. Additionally or alternatively, a capacity of the battery can lie in the range from 1 Ah to 50 Ah. Alternatively, capacities above of up to 100 Ah or of up to 200 Ah can also be used, depending on the required measuring accuracy. In the case of capacities above 200 Ah, a third current magnitude and optionally also a fourth current magnitude and optionally also a fifth current magnitude can furthermore be drained from the battery in addition to the first current magnitude and of the second current magnitude, as already noted above. All of the respectively selected current magnitudes are switched over periodically. The measuring accuracy can advantageously be increased in this way in the case of large battery capacities.

FIG. 2 schematically shows a current-voltage curve diagram 200 of an idealized battery during a measuring process 208 for determining the internal resistance of the battery 400 with two current magnitudes 212 and 214. The drained current magnitude 204 and the measured battery voltage 202 are plotted on the ordinate, the abscissa describes the time 206. With the onset of the measuring process 208, the first current magnitude 212 is provided, which flows during the entire measuring process 208. It forms a type of offset, to which an additional current is added regularly in order to form the second current magnitude 214. Corresponding to the current magnitude 204, the output voltage 202 of the battery 400 decreases. In the case of the first (smaller) current magnitude 212, the no-load voltage 220 (or open circuit voltage 220) of the battery 400 is reduced to the first voltage 222 by a first amount. In the case of the second (larger) current magnitude 214, the no-load voltage 220 of the battery 400 is reduced to the second voltage 224 by a further amount. At the end of the measuring process 208, the current magnitude 204 is zero again and the no-load voltage 220 of the battery is (approximately) at its original value again. The changes of the voltage 202 correspond to the changes of the current magnitude 204. A modified image results in the case of real batteries.

FIG. 3 schematically shows a current-voltage curve diagram 200 of a real battery 400 during a measuring process 208 for determining the internal resistance of the battery 400 with two current magnitudes 212 and 214. FIG. 3 shows a view, which is comparable with FIG. 2, of drained current magnitudes 204 and battery voltages 202 during the measuring process 208. For the sake of clarity, the current magnitude 204 and the resulting battery voltage are illustrated in separate diagrams here, in the case of which the abscissae of the time 206 correspond to one another. The curve of the current magnitudes 204 illustrated in the upper diagram is comparable with the curve of FIG. 2. A significant deviation can be observed in the case of the curve of the battery voltage 202. As already specified above, the battery voltage 202 drops strongly at the beginning of the measuring process 208. In the course of further measuring periods with the switch-over 130 between the two current magnitudes 212 and 214, the voltage 202 recovers gradually, in order to adopt an approximately constant value after a certain number of measuring periods.

The change of the voltage 202 already during the drain of a current magnitude can further be gathered from the diagram 200. On closer examination, the battery voltage is furthermore not constant within the respective duration 210 even after a certain number of measuring periods. The lower voltage value 224 thereby increases when the high current magnitude 214 is applied, while the upper voltage value 222 decreases when the lower current magnitude 212 is applied, as is displayed schematically in diagram 200 in the circular sections. For example, the curve of the upper voltage value 222 reverses within the respective duration after reaching the value, which is approximately constant compared to the previous measuring periods, i.e. in the section 209. It can therefore be useful to vary the detected subsets 209 of the first and of the second voltage 222 and 224 in the course of the measurement.

According to FIG. 4, the battery 400 is discharged via a first measuring resistor 480 in order to drain the first current magnitude 212, and via a second measuring resistor 490 in order to drain the second current magnitude 214. The drain of the second current magnitude 214 can alternatively take place via a parallel connection of the first measuring resistor 480 and of the second measuring resistor 490. Measuring values of the measuring resistors 480 and/or 490 of a measuring apparatus 50 (for example shown in FIG. 5), on which the first current magnitude 212 and the second current magnitude 214 are based, can thereby be stored in the measuring apparatus 50. The measuring values can be determined during a calibration of the measuring apparatus 50. The measuring values of the measuring resistors 480 and/or 490 of the measuring apparatus 50 can thereby optionally be at least ten times larger than the internal resistance of the battery 400. The measuring resistors 480 and/or 490 for the first current magnitude can further optionally be 7.5 ohm and can be 3.75 ohm for the second current magnitude. Discharge currents of 4.5 A or 9.0 A, respectively, can advantageously be achieved in this way, which contribute to the improvement of the measuring accuracy. The measurement of the first current magnitude and of the second current magnitude can further advantageously be forgone by storing the measuring values or nominal values of the measuring resistors 480 and/or 490 in the measuring apparatus 50, which simplifies the measuring apparatus 50.

In other words, FIG. 4 shows a schematic illustration of an electrical circuit 40 (for example controlled by a controller) with connected battery 400 for determining an internal resistance of the battery 400. The described connections are electrically conductive connections. The battery 400, which is illustrated by dashed lines, is described by the equivalent circuit diagram of a battery 400 consisting of an internal resistance connected in series and of an ideal direct current source.

The positive pole of the battery 400 is connected to the circuit 40 via contact points 430. The upper contact point 430 is connected to the first switch 450 and simultaneously to the second switch 460. The first switch 450 is connected to the first measuring resistor 480. The second switch 460 is connected to the second measuring resistor 490. The values of the measuring resistors can be known, for example, from a calibration of the circuit and can be stored in the corresponding controller. The first measuring resistor 480 and the second measuring resistor 490 are jointly connected to the lower contact point 430. The lower contact point 430 is connected to the negative pole of the battery.

A plurality of battery types can be connected, which can comprise lithium-, lead-, nickel-, sodium-, silver-, and tin-based accumulators. Typical voltages of the battery lie between 24 volt (24 V) and 48 volt (48 V), without being limited thereto. The contact points 430 are configured as electrically conductive connecting elements. They can comprise (non-illustrated) pole terminals for connection to the battery 400 and lines fastened to the pole terminals. On their respective other ends, the lines can be connected to connectors, which establish an electrically conductive contact to the circuit of the controller. The ohmic resistance of the electrically conductive connecting elements can be known and can be stored in the corresponding controller 50. The first and second measuring resistors 480 and/or 490 can be formed by means of individual ohmic resistors. They can have values of 7.5 ohm and 3.75 ohm with alternating circuit actuation. Alternatively, both measuring resistors 480 and/or 490 can be configured with 7.5 ohm, in particular when the first switch 450 for the first current drain always remains closed, while the second switch 460 for the first current magnitude 212 is open and is closed only for the second current magnitude 214. In the latter case, the index “ON” and “OFF” in FIGS. 2 and 3 can correspond to the state of the second switch 460.

For thermal relief, the measuring resistors 480 and/or 490 can each be configured as a parallel connection of two or more discrete resistors.

The switches 450 and/or 460 can be configured as relays. Alternatively, the switches 450 and/or 460 can also be configured as transistors, in particular as field effect transistors. During a measurement by means of connection of the second measuring resistor 490 for the second current magnitude, the first switch can be configured as relay (for the slow switching at the beginning and end of the measuring process 208) and the second switch can be configured as transistor (for the quick switch-over 130).

The activation of the switches can take place by means of a controller 50 (for example a processor of the corresponding controller), as will be described in more detail below.

During the periodic switch-over 130 between the first and second current magnitude 212 and 214, the above-mentioned switches 450 and 460 can be configured as field effect transistors (not shown in FIG. 4). In this case, the switch-over between the first and the second resistor 480 and 490 takes place by means of field effect transistors. Alternatively, the second measuring resistor 490 can be connected in parallel to the first measuring resistor by means of a field effect transistor.

A frequency of the periodic switch-over 130 can thereby be larger than or equal to 100 Hz. The frequency of the periodic switch-over can lie between 100 Hz and 5 kHz in this way. The accuracy of the measurement is advantageously increased further in this way. With the use of the field effect transistors, a practical limitation of the level of the switch-over frequency is further advantageously avoided. Installation space is additionally saved when realizing the solution.

The measuring values can be corrected by the resistance of electrically conductive connecting elements between the battery 400 and the measuring apparatus (for example the circuit 40 and/or the controller 50). The resistance can thereby be limited to the ohmic proportion (real proportion of the impedance). The resistance of the electrically conductive connecting elements can further optionally be stored in the measuring apparatus 50. This can be a value, which is measured during the manufacture of the measuring apparatus 50. Alternatively, it can also be a constant value, which is stored during the manufacture. Further alternatively, the value can also be ignored if it lies below a predefined threshold. In embodiments, the threshold can be 1 milliohm. Alternatively or additionally, the resistance can be input by an operator. The measuring accuracy can advantageously be improved further in this way by reducing the determined resistance of battery and electrically conductive connecting elements by the resistance of the electrically conductive connecting elements.

Alternatively, the first current magnitude 212 and the second current magnitude 214 can be kept constant by means of a regulation (not shown in FIG. 4). Possible resistance changes of ohmic components with regard to aging, heat-up, or other environmental influences, which would reduce the measuring quality, can advantageously be countered in this way.

In each exemplary embodiment, the first current magnitude 212 and the second current magnitude 214 can have a ratio of 1 to 2. As an example, the first current magnitude can be 4.5 A and the second current magnitude can be 9.0 A. The selected current magnitudes advantageously allow for the measurement of capacities of the battery of between 1 Ah and 100 Ah. For an increased measuring accuracy (for example compared to the DC measurement), the capacity lies between 1 Ah and 50 Ah. If more than 2 current magnitudes are optionally used during the periodic measurement, for example during the measurement of a battery 400 with more than 100 Ah, each further current magnitude can in each case be increased by the amount of the first current magnitude, based on the previous current magnitude. More than 2 current magnitudes are to be provided for an improved accuracy in particular in the case of a battery capacity of more than 200 Ah.

According to FIG. 5, a second aspect relates to a controller 50 for determining an internal resistance of a battery 400. The controller 50 can correspond to the measuring apparatus and/or comprise the circuit 40. The controller 50 can further advantageously be designed to be functionally integrated into a device.

The controller 50 can optionally further be configured to determine the internal resistance (impedance) at regular time internals and to analyze the change tendency (for example by means of corresponding instructions in the memory 520 for the processor or microcontroller 510). In the case of specified deviations of the internal resistance, the user can be informed about the state of the battery 400 in this way. Advantageously, it is possible to identify a creeping or a sudden change of the internal resistance of the battery by means of this measuring and evaluation method 10. An aging process of the battery 400 can further be derived from this value, and a defect of the battery 400 can further be detected in due time.

In other words, FIG. 5 shows a schematic illustration of a controller 50 with connected battery 400 for determining an internal resistance of the battery, which comprises the electrical circuit 40 and further elements. The controller 50 additionally comprises a processor 510 for the sequential control of the controller 50, for example according to the method 10. The controller 50 further comprises a memory 520, which comprises a program for performing the measurement for determining an internal resistance of the connected or connectable battery 400, as well as optionally for storing the detected measuring values and the results determined therefrom. The controller 50 further comprises the contact (or connecting) points 430 for electrically contacting the battery 400 as well as optionally a data interface 560 for inputting and outputting data.

The processor 510 controls the measuring method for determining an internal resistance of the connected battery. It controls the provision of the first and second (and optionally further) current magnitudes, the detection of the respective battery voltages, optionally the suppression of certain detected voltages and/or the suppression of certain phases of the respectively detected battery voltage. To determine an internal resistance of the battery, the difference of the voltages is thereby compared to the difference of the currents of the observed subsets of the measuring periods, and is reduced by the resistance of the connecting elements between battery and controller.

The internal resistance of the battery 400 can be determined according to the following formula

$${R}_{i} = \vert \frac{{\sum }_{i = n - m + 1}^{n} \frac{dU}{dI}}{m} \vert - {R}_{Verb}$$

Rᵢ is thereby the internal resistance in ohm of the battery, n is the number of the switch-over cycles of the different current magnitudes of the measuring process, m is the number of the evaluated switch-over cycles, dU is the measured voltage difference in the case of the different current magnitudes, dI is the current difference of the different current magnitudes, and R_{Verb} is the ohmic resistance of the connecting elements between battery and controller. In the case of a measuring method 10 with more than two different current magnitudes 212 and 214, the evaluation is to be adapted accordingly. This can take place by comparing the effective voltages and the effective currents. The following formula can be applied thereby:

$${R}_{i} = \frac{{U}_{eff}}{{I}_{eff}} .$$

U_{eff} is thereby the effective voltage of all measured voltages, I_{eff} is thereby the effective current magnitude of all provided current magnitudes.

The internal resistance of the battery Rᵢ can be determined at regular time intervals and its change tendency can be analyzed. In the case of specified deviations of the impedance, the operator can be informed about the state of the battery. It is therefore possible to identify a creeping or a sudden change of the internal resistance of the battery by means of this measuring and evaluation method. The aging process can be analyzed from this value, and a defect of the battery can be detected in due time.

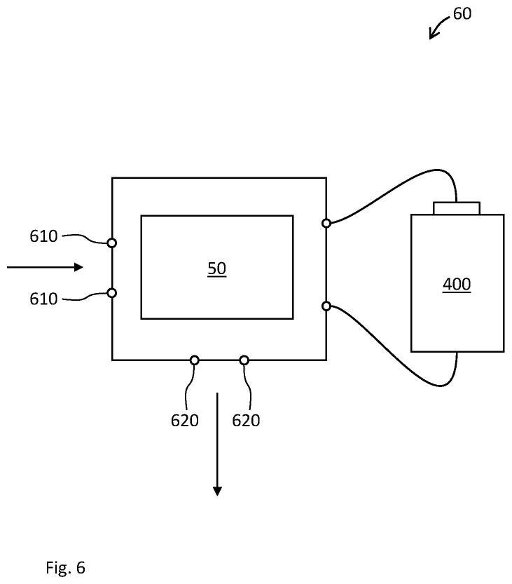

According to a third aspect, FIG. 6 schematically shows an embodiment of an uninterruptible (interruption-free) power supply (UPS) 60. The latter can comprise a battery 400 (not shown in FIG. 6) or can be capable of being electrically conductively connected to the battery. It can comprise the controller 50 for determining an internal resistance of the battery 400 according to the second aspect. A cost-efficient monitoring function, which, on the basis of the determined internal resistance of the connected battery, can check the functionality of the latter, can advantageously be integrated into the interruption-free power supply in this way. FIG. 6 furthermore shows the terminals of the primary power supply 610 as well as the terminals 620, which the power supply provides for the loads, which are to be connected.

In other words, the invention can also be illustrated as follows. The measuring and evaluation method described here can be used for determining the impedance (of the internal resistance) of a battery during operation on an uninterruptible (interruption-free) power supply (UPS). This measuring and evaluation method can provide information about the state of the connected battery. The internal resistance (impedance value) can be determined at regular time intervals and the change tendency can be analyzed. In the case of specified deviations of the internal resistance, the user can be informed about the state of the battery. It is possible to detect a creeping or a sudden change of the impedance of the battery by means of this measuring and evaluation method. The aging process can be analyzed from this value, and a defect of the battery can be detected in due time.

The impedance of a battery moves in the range of a few milliohm (in the case of the batteries with large capacities) up to several hundred milliohm (in the case of the batteries with small capacities). An interruption-free power supply must be able to analyze each connected battery and to provide reliable information about the quality of the battery, independently of capacity and type.

Currently known measuring methods of the battery impedance (i.e. of the internal resistance) provide either good results, for example AC measurements (i.e. alternating current measurement) with alternating current or become too inaccurate in the case of higher battery capacities, for example DC measurement (i.e. direct current measurements) with direct current values. However, the AC measurement requires a complex and cost-intensive measuring apparatus, which is not suitable for a mass production of the UPS units. The DC measurement, in contrast, is of simple construction and is suitable for the mass production of the UPS units but does not provide the desired accuracy of the information about the quality of the battery in the case of a broad spectrum of the connected batteries.

The measuring and evaluation method described here is based on the more cost-efficient DC measuring apparatus, wherein the method and the evaluation method were newly developed, so that the desired accuracy of the information is also attained in the case of the batteries with large capacities.

In the case of the measuring and evaluation methods described here, a modified DC measurement is used as measuring method. In contrast to the known DC measuring method, where the measurement of the no-load voltage and the measurement of the battery voltage with a connected load resistor already provides the result, two different load resistors are alternately connected to the battery in the case of the method according to the invention (see FIG. 4).

A battery 400 can be described as a series connection of an ideal voltage source and of an internal resistance. For the complete measurement, the first switch 450 and the second switch 460 are activated consecutively (i.e. closed or electrically conductive). In the case of current load with the first current magnitude 212, a voltage drops at the internal resistor 480. In the case of the current load with the second current magnitude 214, when the second switch 460 is activated, the voltage drops at the second measuring resistor 490. The internal resistance of the battery can then be calculated from the two values of the first voltage 222 and of the second voltage 224 and from the known first and second current magnitudes 212 and 214.

The second difference of the measuring method can be the duration of the measurement. In the case of the known DC measuring method, two measurements are performed, a no-load measurement and a load measurement. In the case of the inventive measuring and evaluation method, the advantage of an AC measurement is used, and the battery is loaded several times in a row (see FIG. 5).

In the case of the measuring and evaluation method according to the invention, the connected battery can be subjected to several rectangular pulses. The total duration of the load, the first current magnitude-to second current magnitude ratio, and the pulse width can be selected according to the battery capacity, in order to be able to perform optimal measurement, and in order to obtain highly accurate measuring values. In exemplary embodiments, the duration of the load with the first current magnitude to the second current magnitude can be identical. The total duration of the measurement can depend on the used component parts.

The calculation is based on the determination of the battery voltage during the two-stage periodic load of the battery. The resistance value for the battery load current calculation can be stored in the UPS as two constants, the voltage is detected by the UPS. For this reason, a separate current measurement can be forgone. The calculated resistance value can be adjusted, in that the resistance value of the connected lines and terminals is subtracted.

An expansion of the measuring method for more accuracy can be designed as follows. The accuracy obtained in practice is sufficient for the inventive application. The demand on the accuracy in the case of the currently used batteries up to 200 Ah is reached by means of two load stages, independently of the battery type or the used chemical substances, respectively. When using larger battery capacities and/or in the case of higher demands on the accuracy of the measurement, the circuit from FIG. 4 can be expanded by one or several stages, and the calculation model can be adapted. The accuracy of the measurement can be improved by means of further measures, such as RMS calculation of voltage and current values, as well as by means of the adaptation of the switching frequency of the switches (for example between 100 Hz to 5 kHz). An expansion of the circuit 40 by further additional switches beyond the available switches 450 and 460 is also associated with an improvement of the accuracy, in particular in the case of higher capacities of the battery.

Analyses have shown that a conventional DC measurement cannot provide a necessary measuring accuracy because the battery voltage drops strongly in the case of only one (in the method according to the invention—first) load pulse. In the case of further load pulses, the battery voltage does not drop so strongly. The measuring accuracy increases with each further pulse (see FIG. 3). For evaluation and calculation purposes, several pulses (e.g. the last 10) can be observed in the second half of the measuring cycle, when the measured voltage stabilizes (no larger vibrations can be determined, has “calmed down”). To increase the measuring accuracy, the measuring data detection can additionally be performed in the last third of a pulse. An average value from several measuring values can once again increase the accuracy of the measurement.

All rechargeable electrochemical batteries (accumulators) can be evaluated by means of exemplary embodiments of the measuring and evaluation method 10 according to the invention, independently of type and capacity.

Due to the described measuring and evaluation method 10, it is furthermore possible to consider the quality of the installation, thus of the distance (cable, terminal connection, etc.) between the UPS and the battery in corresponding exemplary embodiments.

While the invention has been illustrated and described in detail in the drawings and foregoing description, such illustration and description are to be considered illustrative or exemplary and not restrictive. It will be understood that changes and modifications may be made by those of ordinary skill within the scope of the following claims. In particular, the present invention covers further embodiments with any combination of features from different embodiments described above and below. Additionally, statements made herein characterizing the invention refer to an embodiment of the invention and not necessarily all embodiments.

The terms used in the claims should be construed to have the broadest reasonable interpretation consistent with the foregoing description. For example, the use of the article “a” or “the” in introducing an element should not be interpreted as being exclusive of a plurality of elements. Likewise, the recitation of “or” should be interpreted as being inclusive, such that the recitation of “A or B” is not exclusive of “A and B,” unless it is clear from the context or the foregoing description that only one of A and B is intended. Further, the recitation of “at least one of A, B and C” should be interpreted as one or more of a group of elements consisting of A, B and C, and should not be interpreted as requiring at least one of each of the listed elements A, B and C, regardless of whether A, B and C are related as categories or otherwise. Moreover, the recitation of “A, B and/or C” or “at least one of A, B or C” should be interpreted as including any singular entity from the listed elements, e.g., A, any subset from the listed elements, e.g., A and B, or the entire list of elements A, B and C.

### LIST OF REFERENCE NUMERALS

10 Flowchart for a method of determining an internal resistance of a rechargeable electrical energy storage
40 Circuit for measurement purposes
50 Controller
60 Uninterruptible (or interruption-free) power supply
100 Start of the method
110 Detecting a first voltage of the energy storage
120 Detecting a second voltage of the energy storage
130 Periodic switch-over
140 Determining the internal resistance of the energy storage
150 Subset detection of all voltages
160 Subset detection of the voltages at the end of the measuring process
170 Detection according to a threshold value of the first voltage and/or of the second voltage
180 Sectional detection of the first voltage and/or of the second voltage
190 Process completion
202 Terminal voltage UBatt of the energy storage, for example voltage curve at the battery terminals
204 Current magnitude IBatt drained from energy storage
208 Measuring process
209 End of the measuring process
210 Duration of the first and/or second current magnitude
211 Section of the duration of the first and/or second current magnitude
212 First current magnitude ION1 of the energy storage
214 Second current magnitude ION2 of the energy storage
220 Nominal or no-load voltage (or open circuit voltage) of the energy storage
222 First voltage UON1 of the energy storage
224 Second voltage UON2 of the energy storage
400 Electrical energy storage, for example battery
430 Contact (or connecting) points of the battery to the circuit
450 First switch, for example first field effect transistor
460 Second switch, for example second field effect transistor
480 First measuring resistor
490 Second measuring resistor
510 Processor of the controller
520 Memory of the controller
560 Data line connections
610 Terminals of the primary power supply
620 Terminals of the power supply for the loads to be connected

1. A method of determining an internal resistance of a rechargeable electrical energy storage, comprising:
detecting a first voltage of the energy storage while a first current magnitude is drained from the energy storage;
detecting a second voltage of the energy storage while a second current magnitude is drained from the energy storage, the second current magnitude being larger than the first current magnitude;
implementing a periodic switch-over between the drain of the first current magnitude and the drain of the second current magnitude; and
determining the internal resistance based on the detected first and second voltages, which are detected by the periodic switch-over between the first and second current magnitudes.

2. The method of claim 1, wherein the internal resistance is determined based on a subset of the detected first and second voltages.

3. The method of claim 2, wherein the subset of the detected first and second voltages comprises a subset of the first and second voltages detected towards an end of a measuring process and/or excludes a subset of the first and second voltages detected at a beginning of a measuring process.

4. The method of claim 3, wherein a change rate of the first voltage and/or of the second voltage is larger than a first threshold value during the excluded beginning of the measuring process, and/or
wherein a change rate of the first voltage and/or of the second voltage is smaller than a second threshold value during the subset detected towards the end of the measuring process.

5. The method of claim 1, wherein, to determine the internal resistance per duration of the first and second current magnitude, the first or second voltage, respectively, is detected only in one section of the duration.

6. The method of claim 1, wherein the first and second current magnitude are each constant with a rectangle-shaped curve of the current magnitude.

7. The method of claim 1, wherein the duration of the drain of the first and second current magnitude are identical, and/or
wherein a duty cycle of the duration of the first and second current magnitude is proportionate to a period duration of the switch-over and/or a frequency of the periodic switch-over is independent of a capacity of the rechargeable electrical energy storage.

8. The method of claim 1, wherein the rechargeable electrical energy storage comprises electrochemical cells, and/or
wherein a nominal voltage or no-load voltage of the rechargeable electrical energy storage is in a range from 12 V to 48 V, and/or
wherein a capacity of the rechargeable electrical energy storage is in a range from 1 Ah to 100 Ah.

9. The method of claim 1, wherein the rechargeable electrical energy storage is discharged via a first resistor in order to drain the first current magnitude and is discharged via a second resistor or via a parallel connection of the first resistor and of a second resistor in order to drain the second current magnitude, and/or
wherein measuring values of resistors of a measuring apparatus, on which the first current magnitude and the second current magnitude are based, are stored in the measuring apparatus, and/or
wherein measuring values of the resistors of the measuring apparatus are at least ten times larger than the internal resistance.

10. The method of claim 9, wherein, when periodically switching over between the first and second current magnitude, a switch-over takes place between the first and second resistors by a field effect transistor or the second resistor is connected in parallel to the first resistor by a field effect transistor.

11. The method of claim 10, wherein the measuring values are corrected by a resistance of electrically conductive connecting elements between the electrical energy storage and the measuring apparatus.

12. The method of claim 1, wherein the first current magnitude and the second current magnitude are kept constant by a regulation.

13. The method of claim 1, wherein the first current magnitude and the second current magnitude have a ratio of 1 to 2.

14. A controller for determining an internal resistance of a rechargeable electrical energy storage, the controller being configured to perform the method of claim 1.

15. An uninterruptible power supply, comprising:
a rechargeable electrical energy storage, or the uninterruptible power supply is electrically conductively connectable a rechargeable electrical energy storage; and
the controller of claim 14.

16. The method of claim 4, wherein the second threshold value is smaller than or equal to the first threshold value.

17. The method of claim 5, wherein, to determine the internal resistance per duration of the first and second current magnitude, the first or second voltage, respectively, is detected at an end or in a last quarter of the duration of the first or second current magnitude, respectively.

18. The method of claim 9, wherein a frequency of the periodic switch-over is larger than or equal to 100 Hz.
